(19) United States
(12) Patent Application Publication
(10) Pub. No.: US 2002/0011662 A1
(43) Pub. Date: Jan. 31, 2002

(54) Packaging substrate and semiconductor device

(76) Inventors: Yasumoto Komiya, Yokohama (JP); Takashi Suga, Yokohama (JP); Yoshihiko Hayashi, Tokyo (JP)

Correspondence Address: ANTONELLI TERRY STOUT AND KRAUS, SUITE 1800, 1300 NORTH SEVENTEENTH STREET, ARLINGTON, VA, 22209

(21) Appl. No.: 09/839,415

(22) Filed: Apr. 23, 2001

(30) Foreign Application Priority Data
Apr. 21, 2000 (JP) 00-126285

(51) Int. Cl. H01L 23/34

(52) U.S. Cl. 257/728

(57) ABSTRACT

A low-impedance connection is provided between an LSI and a capacitor (for example, existing internal capacitance of an electronic part) in the power supply path to limit power supply noise, which can be a factor in high-speed logic circuit malfunctions. For example, a packaging substrate and a semiconductor device using the same are provided which reduce power supply path inductance, which is a major factor in impedance.

### BACKGROUND OF THE INVENTION

The present invention relates to a power supply structure in a high-speed logic circuit.

In high-speed logic circuits such as LSIs, malfunctions caused by the noise that accompanies higher operating speeds have been a major issue. One of the factors behind this noise is the power supply noise caused by variations in the power supply voltage within the LSI. Power supply current can vary greatly with changes in the activation rate of logic gates in high-speed logic circuits such as LSIs. This results in variations in the power supply voltage, which is the product of the current and the power supply impedance of the power supply system as seen from the logic gates.

The power supply impedance of the power supply system is the impedance between the power supply layer and the ground layer. One effective method for reducing this impedance is to insert capacitors as appropriate in the power supply-ground trunk line.

Standard packaging methods include forming capacitor cells within the LSI and mounting bypass capacitors on the substrate. However, there is a limit to the capacitance that can be equipped within the LSI since this can lead to increased chip size. Also, at high frequency ranges, the inductance in the power supply trunk lines connecting internal capacitances can increase impedance, thus preventing effective use of internal capacitance. With bypass capacitors mounted on the substrate, there is a limit to how close to the LSI these can be mounted, thus limiting inductance reduction. Also, the inductance of the power supply path to the LSI will increase impedance at high frequency ranges. Inductance increases based on co (=2πf)×L (f: frequency, L: inductance).

FIG. 5 shows an MCC system presented in Japanese laid-open patent publication number Hei 4-211191, which provides an improved power supply structures that addresses these problems. In this system, a multi-layer chip carrier (MCC) 501, formed from ceramic or the like and containing a capacitor layer 502, is inserted between an LSI 101 and a substrate 103. By providing a capacitor close to the LSI, the inductance of the power supply path to the LSI is lowered and the impedance of the internal capacitance of the LSI, the bypass capacitor, and the power supply are reduced. However, the MCC 501 in this system involves high production costs and the direct material costs as well as the increases in the number of assembly steps leads to increased costs.

### SUMMARY OF THE INVENTION

The object of the present invention is to provide a packaging substrate and a semiconductor device using the same that effectively uses existing capacitance within an electronic part to reduce power supply impedance in a power supply system for the electronic part.

In order to achieve the object described above, the present invention is provided as described in the claims of the invention. A low-impedance connection is formed between an LSI and a capacitor (an existing capacitance within an electronic part) in a power supply path. In particular, inductance in power supply paths, which is a major factor in impedance, is reduced.

More specifically, the present invention provides a packaging substrate that includes a power supply layer. An electronic part receiving power from the power supply layer by way of bumps is mounted on the packaging substrate. The inductance of the power supply layer corresponding to a distance between the power supply bumps is less than an inductance of a connection section between the substrate and the electronic part.

According to another aspect of the invention, the electronic part is an LSI and the connection section provides a connection using a solder ball.

According to another aspect of the invention, an insulative film in the power supply layer is formed with a thickness of approximately 3 to 30 microns.

According to another aspect of the invention, the power supply layer is electrically connected to a capacitor and the power supply bumps of the LSI.

According to another aspect of the invention, the inductance between power supply bumps is less than an inductance of a connection section with a substrate.

According to another aspect of the invention, the connection section includes a connection structure that uses a solder ball.

According to another aspect of the invention, a semiconductor device includes a substrate including a power supply layer and an electronic part receiving power from the power supply layer and mounted on the substrate via bumps. An inductance of the power supply layer corresponding to a distance between the power supply bumps is less than an inductance of a connection section between the substrate and the electronic part.

### BRIEF DESCRIPTION OF THE DRAWINGS

FIG. 1 is a drawing showing the architecture of a substrate on which an LSI and the like are mounted.

FIG. 2 is a drawing showing the arrangement of bypass capacitors.

FIG. 3 is a drawing showing the structure of bumps on an LSI.

FIG. 4 is a drawing showing a two-dimensional equivalent circuit model of the packaging structure from FIG. 1.

FIG. 5 is a drawing showing a conventional packaging structure.

FIG. 6 is a drawing showing results of an analysis of inductance between power supply bumps of a power supply layer connecting an LSI and bypass capacitors.

FIG. 7 is a drawing showing impedance frequency characteristics.

FIG. 8 is a drawing showing the architecture of a substrate on which an LSI and the like are mounted.

### DETAILED DESCRIPTION OF THE PREFERRED EMBODIMENTS

FIG. 1 shows a schematic drawing of an LSI module power supply structure according to the present invention.

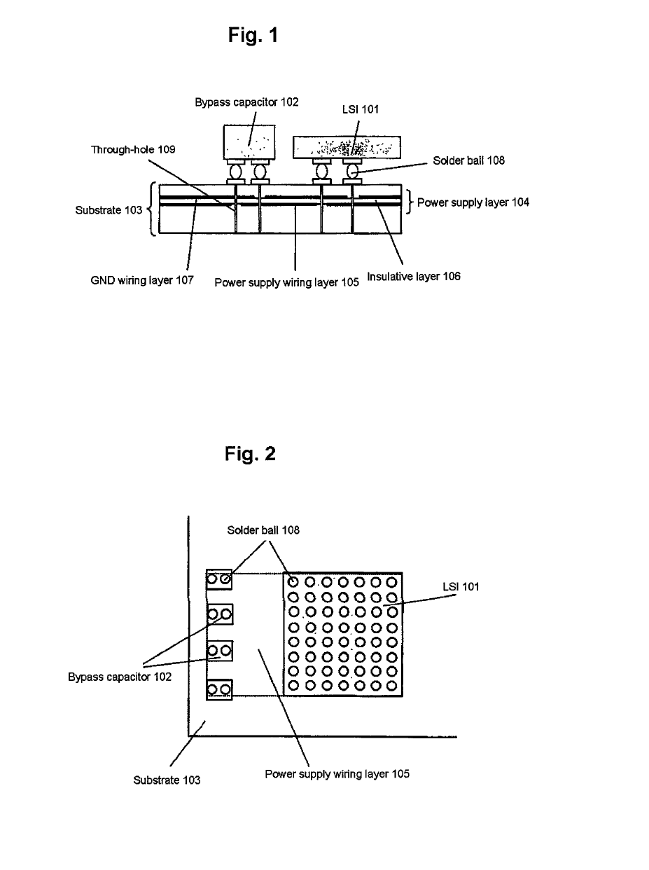

In the figure, a substrate 103 includes a power supply layer 104 formed as an internal layer. Bypass capacitors 102 and an LSI 101 mounted on the substrate 103 are respectively connected via through-holes 109 to a power supply wiring layer 105 and a ground wiring layer 107 formed in the power supply layer 104. The LSI 101 is a BGA-type LSI with solder balls 108. The bypass capacitors 102 are mounted near (1-10 mm) the LSI to provide improved impedance reduction. Also, as shown in FIG. 2, there are multiple bypass capacitors 102 mounted along one side of the LSI 101. The solder balls 108 are used to provide low-impedance connections between the bypass capacitors 102 and the substrate 103.

As shown in FIG. 3, power supply bumps 301 and ground bumps 302 are disposed as an area array on the LSI 101.

The bumps are arranged in a uniform manner and are separated by uniform intervals. The power supply bumps 301 and the ground bumps 302 are also arranged in a uniform manner amongst themselves. Rows of bumps containing the power supply bumps 301 are alternated with rows of bumps containing the ground bumps 302. In these rows, the power supply bumps 301 and the ground bumps 302 are alternated with signal bumps.

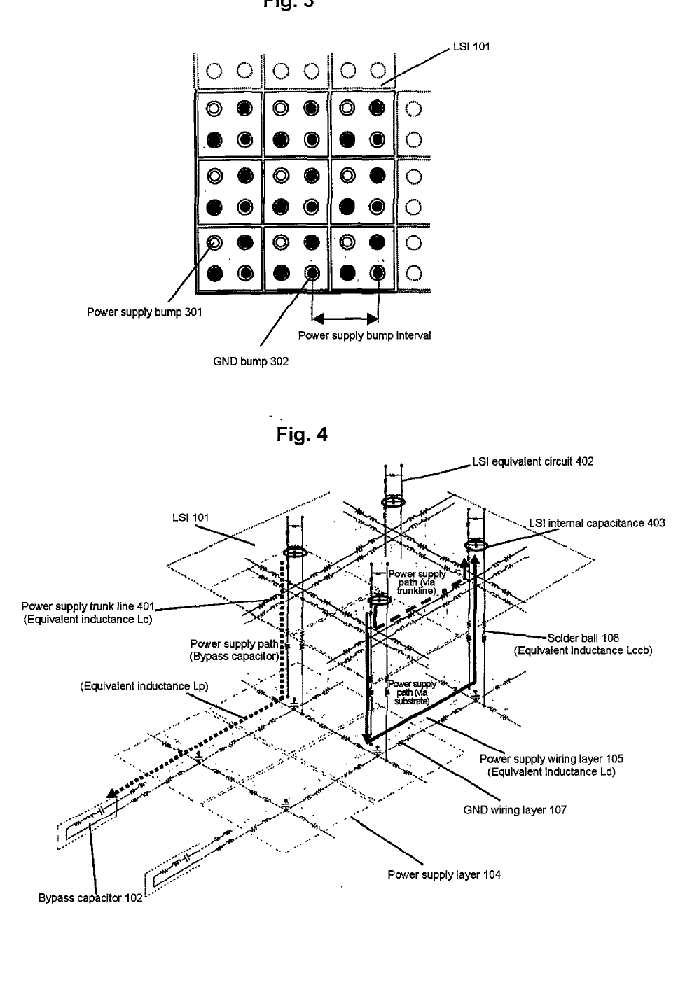

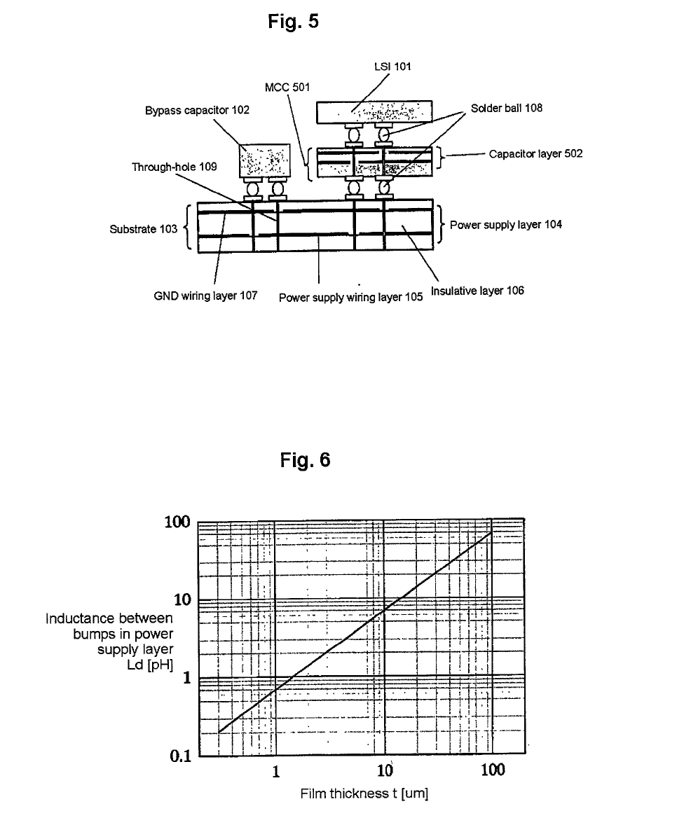

FIG. 4 shows a two-dimensional equivalent circuit model of this power supply structure, where the circuit model is set up so that each power supply bump 301 is associated with an LSI equivalent circuit. The equivalent circuit in FIG. 4 includes the bypass capacitors and the like as circuit elements. Also, the LSI is modeled with a packaging structure in which the power supply bump interval is 1 mm. Also, each of the LSI equivalent circuits 402 has an internal LSI capacitance 403. In the actual product, the distance between the LSI 101 and the bypass capacitors 102 is approximately 1-10 mm, and this is up to approximately ten times the distance between the internal LSI capacitances 403.

Power supply trunk lines 401 connecting the equivalent circuits 402 in the LSI are formed very fine due to the high degree of integration in the LSI. The equivalent inductance Lc thereof is generally 200-300 pH for a 1 mm lattice block. This inductance is sufficiently higher than the equivalent inductance of the solder balls, which is approximately Lccb=20 pH. Thus, for high frequency ranges, it is more difficult to establish the power supply path (via trunk line) by way of the power supply trunk line 401, as indicated by the dotted line, compared to the path going through the solder balls 108 and to the bypass capacitor 102 or the like.

The power supply path (via trunk line) going through the power supply trunk line 401 as indicated by the dotted line can be established more easily by making the power supply trunk line 401 have a lower impedance than the solder bumps. Modifying the internal structure is not practical, however, in cases such as when a purchased LSI is being packaged. If the internal capacitances 403 of adjacent LSI equivalent circuits 402 can be used effectively, i.e., if the charge from the LSI internal capacitance 403 can be provided more easily, the power supply impedance can be reduced.

Thus, the inventors decided to reduce the power supply impedance by taking advantage of the LSI internal capacitance 403 through the use of the power supply path (via substrate), which goes through bumps and the substrate, as indicated by the solid line.

Also, the use of solder balls to connect the LSI and the substrate reduces the inductance L (L=Ld+2Lccb) in the power supply path connecting the internal capacitances of the LSI by way of the power supply layer in the substrate. This reduction provides further improvements in the impedance reduction achieved with the LSI internal capacitances 403.

The dimensions of the solder balls are determined by conditions relating to connection reliability, bump pitch, and the like, thus imposing restrictions on how much the equivalent inductance Lccb can be reduced.

For this reason, it was decided to maximize reduction of the inductance L (L=Ld+2Lccb) of the power supply path (via substrate), which connects the LSI internal capacitances 403 via the power supply wiring layer 105 in the substrate, by making the equivalent inductance Ld between the power supply bumps on the substrate side smaller than the equivalent inductance Lccb. This allows the internal capacitances 403 of adjacent LSI equivalent circuits to be used effectively with the power supply path (via substrate), thus providing efficient reduction of power supply impedance.

Also, reducing the inductance of the power supply layer 104 allows the inductance Lp between bypass capacitor 102 and the LSI 101 mounted on the substrate. Thus, the charge from the bypass capacitor 102 can be supplied easily and the impedance of the power supply system at high frequency ranges can be reduced.

In other words, by reducing the inductance of the power supply layer 104, both the internal capacitances 403 of adjacent LSI equivalent circuits and the bypass capacitors 102 can be used effectively. Even if the bypass capacitors 102 are positioned as close to the LSI as possible, however, the inductance of the power supply path to the bypass capacitors 102 will be greater than the inductance of the power supply path that uses the internal capacitances within the LSI. Thus, using internal capacitances is more effective in reducing impedance for high frequency ranges of f=10 MHz or higher.

As shown in FIG. 1, an insulative layer 106 is formed in the power supply layer 104 connecting the LSI 101 and the bypass capacitors 102. The insulative layer 106 is formed with a thickness of no more than 30 microns. It was found that with a thickness of no more than 30 microns, the inductance Ld between the power supply bumps in the power supply layer 104 drops to or below the equivalent inductance Lccb of the solder balls due to the mutual electromagnetic induction between the currents flowing through the power supply wiring layer 105 and the ground wiring layer 107. As a result, a power supply path connecting adjacent internal capacitances 403 in the LSI can be formed with an inductance lower than that of the power supply trunk lines 401.

FIG. 6 shows results from an analysis of inductance between power supply bumps in the power supply layer 104 as it relates to the thickness of the insulative layer 106. The results indicate that the inductance Ld between the power supply bumps is proportional to the thickness t of the insulative layer and can be reduced by forming a thinner layer.

However, forming a film with a thickness of no more than 3 microns can cause defects such as shorts in the power supply layer 104, leading to reduced yield. Thus, 3-30 microns is believed to be an appropriate range for the film thickness.

Taking an LSI module packaged with power supply bumps formed at a 1 mm pitch as an example, forming the insulative layer 106 with a thickness of 3 microns will reduce the inductance between power supply bumps in the power supply layer 104 to 2 pH. This provides an inductance that is 1/10 the equivalent inductance Lccb=20 pH of the solder balls 108. As a result, the power supply path (via substrate) between adjacent internal capacitances 403 in the LSI can be provided with a low inductance of 40-50 pH, leading to a power supply path that has an inductance that is ⅕-⅙ the inductance of the power supply trunk lines 401, for which Lc=200-300 pH.

The reduction of inductance in the power supply layer resulting from using a thin insulative layer 106 also reduces the inductance Lp between the LSI 101 and the bypass capacitors 102. This provides a power supply structure with a power supply layer 104 that reduces the impedance between the power supply and ground for high frequency ranges.

For example, compared to a substrate that uses a power supply layer with an insulative layer 106 that is 100 microns thick, a substrate using a power supply layer with a thickness of 3 microns will provide an inductance Lp between the LSI and the bypass capacitors that is 1/10 or less.

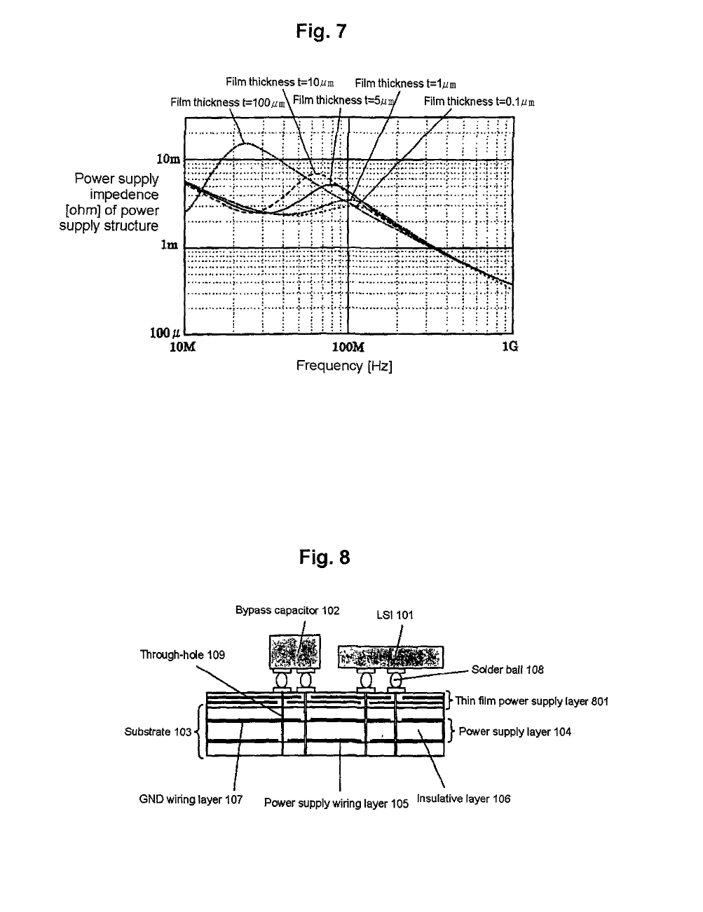

FIG. 7 shows the results of an analysis of power supply impedance frequency characteristics in a circuit that is electronically equivalent to a power supply structure according to the present invention. In the 10 M-1 GHz frequency range, a power supply layer 104 with an insulative layer 106 that is 100 microns thick shows a maximum power supply impedance Z of 15.5 milliohms. A power supply layer 104 formed with an insulative layer 106 that is 5 microns thick can reduce the impedance to approximately ⅓, at Z=5.6 milliohms.

FIG. 8 shows a structure in which a thin-film power supply layer 801 is formed on the mounting substrate. In this power supply structure, the impedance is reduced by reducing the inductance of the power supply path (via substrate) and the power supply path (bypass capacitor).

This structure can be formed and power supply impedance can be reduced simply by adding a process for forming the thin-film power supply layer to a conventional LSI module.

For example, the inductance in the power supply layer between power supply bumps can be reduced significantly from 70 pH to 2 pH by adding a thin-film power supply layer 801 having an insulative layer that is approximately 3 microns thick to the power supply layer 104, which has an insulative layer 106 that is 100 microns thick.

In the embodiments described above, the advantages of the present invention are described with regard to simplified power supply structures formed with a single LSI on a substrate and with multiple bypass capacitors arranged along one side of a single LSI. However, similar advantages can be obtained in power supply structures where multiple LSIs are mounted on a substrate and bypass capacitors are mounted along all four sides of each LSI. Also, similar advantages can be obtained if the interval between power supply bumps on the LSI is a distance other than 1 mm.

Also, the inductance characteristics described above apply not only to solder balls but also connecting structures that use resin such as polymer bumps and bumps formed with metals such as Cu.

Also, the description covered BGA semiconductor devices, but similar advantages can be provided for CSP semiconductors, WPP semiconductors, and the like as well as semiconductor devices that use leads such as QFP semiconductors. Similar advantages can also be provided for bare-chip packaging. The gold bumps of the bare chip are generally connected with ACF, conductive adhesive, solder, or the like, and in this case the connection sections will be considered to include the gold bumps and the ACF or the conductive adhesive or the solder.

The solder used to form the solder bumps should preferably be non-magnetic and low-resistance so that a low-impedance connection can be provided.

As described above, a power supply layer with a thin insulative layer having a thickness of no more than 30 microns can reduce inductance, which is an issue in high frequency ranges. This takes place due to the mutual electromagnetic inductance between current flowing in the power supply wiring layer and the ground wiring layer. As a result, connections between adjacent internal capacitances in the LSI and connections between the LSI and bypass capacitors can be achieved with a low impedance. This allows the charge from the bypass capacitors in the power supply path to be easily supplied, and the impedance between the power supply and ground in the power supply structure can be reduced in a low-cost, low-noise power supply system.

A packaging substrate and semiconductor device having low power supply impedance in the power supply system can be provided with the present invention.

1. In a packaging substrate including a power supply layer,
a packaging substrate wherein:
an electronic part receiving power from said power supply layer by way of bumps is mounted on said packaging substrate; and
an inductance of said power supply layer corresponding to a distance between said power supply bumps is less than an inductance of a connection section between said substrate and said electronic part.

2. A packaging substrate as described in claim 1 wherein said electronic part is an LSI and said connection section provides a connection using a solder ball.

3. A packaging substrate as described in claim 1 wherein an insulative film in said power supply layer is formed with a thickness of approximately 3 to 30 microns.

4. A packaging substrate as described in claim 1 wherein said power supply layer is electrically connected to a capacitor and said power supply bumps of said LSI.

5. A semiconductor device wherein an inductance between power supply bumps is less than an inductance of a connection section with a substrate.

6. A semiconductor device as described in claim 5 wherein said connection section includes a connection structure that uses a solder ball.

7. A semiconductor device comprising:
a substrate including a power supply layer; and
an electronic part receiving power from said power supply layer and mounted on said substrate via bumps;
